(19) United States
(12) Patent Application Publication
(10) Pub. No.: US 2026/0126576 A1
(43) Pub. Date: May 7, 2026

(54) OPTICAL FILTER

(71) Applicant: Commissariat à I'Énergie Atomique et Aux Énergies Alternatives, Paris (FR)

(72) Inventor: Catherine Pelle, Grenoble (FR)

(73) Assignee: Commissariat à I'Énergie Atomique et Aux Énergies Alternatives, Paris (FR)

(21) Appl. No.: 19/374,009

(22) Filed: Oct. 30, 2025

(30) Foreign Application Priority Data
Nov. 4, 2024 (FR) FR2412061

(51) Int. Cl. G02B 5/30; H10F 39/00

(52) U.S. Cl. CPC G02B 5/3041; H10F 39/8053

(57) ABSTRACT

An optical filter including a superposition of: at least first and second resonant cavities; and at least a first polarizing filter.

### CROSS-REFERENCE TO RELATED APPLICATIONS

This application claims priority to French application number FR2412061, filed Nov. 4, 2024. The contents of this application is incorporated herein by reference in its entirety.

### TECHNICAL FIELD

The present disclosure relates generally to optical filters and in particular, polarizing spectral filters. A polarizing spectral filter is an optical filter adapted to transmit predominantly a radiation comprised within at least a certain wavelength range and having at least a certain polarization.

### BACKGROUND ART

Numerous optical filters, inter alia spectral polarizing filters, have been proposed. However, existing optical filters have various disadvantages.

International application WO2018/070269 describes an optical device for eliminating a decrease in the extinction ratio of the transmitted light. However, this optical device only achieves a low intensity contrast between the “s”-polarized light, which has a linear polarization orthogonal to the incidence plane, and the “p”-polarized light, which has a linear polarization parallel to the incidence plane. In addition, the implementation of the device requires a significant etching depth and requests the etching of different materials.

US patent U.S. Pat. No. 9,601,532 describes an optical filter comprising a Fabry-Perot type resonator having a plate-shaped metallic grid polarizer. However, this filter has a low resilience to the incidence angle of the light: the light intensity transmitted by the filter decreases significantly as the incidence angle increases.

European patent EP3839454 describes a polarizing spectral filter comprising a grating made of bars of materials with different optical indices interposed between reflectors each comprising alternating layers of these materials. However, this filter has a narrow transmission band and is highly sensitive to variations in wavelength, thickness, and incidence angle.

### SUMMARY OF INVENTION

There is a need to overcome all or part of the disadvantages of existing optical filters, inter alia of existing polarizing spectral filters. In particular, it would be desirable to improve the resilience to the incidence angle of the existing filters.

To this end, one embodiment provides an optical filter comprising a superposition of:
at least first and second resonant cavities; and
at least a first polarizing filter.

According to one embodiment, the optical filter further comprises a second polarizing filter, the first and second polarizing filters being respectively located in the first and second resonant cavities.

According to one embodiment, the optical filter further comprises a third resonant cavity interposed between the first and second resonant cavities, each first polarizing filter being located in one of the first, second and third resonant cavities.

According to one embodiment, the optical filter comprises a single first polarizing filter preferably located in the third resonant cavity.

According to one embodiment, each resonant cavity is interposed between stacks each comprising an alternation of:
at least two first layers of a first insulating material having a first optical index; and
at least one second layer of a second insulating material having a second optical index strictly higher than the first optical index.

According to one embodiment, the first and second insulating materials are selected from:
oxides, for example silicon oxide, titanium oxide, niobium oxide, tantalum oxide, etc.;
nitrides, for example silicon nitride; and
amorphous silicon.

According to one embodiment, each first layer and each second layer has a quarter-wavelength thickness.

According to one embodiment, each resonant cavity has a half-wavelength thickness.

According to one embodiment, each polarizing filter comprises a grating of alternating parallel bars comprising:
first bars made of a third material having a third optical index; and
second bars made of a fourth insulating material having a fourth optical index strictly higher than the third optical index.

According to one embodiment, the third and fourth materials are respectively identical to the first and second materials.

According to one embodiment, the third material is a metallic material, for example silver or aluminum.

According to one embodiment, the bar gratings of the first and second polarizing filters have an identical pitch.

According to one embodiment, the bar gratings of the first and second polarizing filters have different pitches.

One embodiment provides an optical filter as described, intended to be placed opposite a pixel array of an image sensor, the optical filter being adapted to transmit an incident radiation predominantly in a first wavelength range and according to a first polarization to certain pixels of the sensor, and predominantly in at least a second wavelength range, different from the first wavelength range, and/or according to at least a second polarization, different from the first polarization, to other pixels of the sensor.

One embodiment provides a multispectral or hyperspectral sensor comprising an image sensor having a pixel array opposite which an optical filter as described is located.

### BRIEF DESCRIPTION OF DRAWINGS

The foregoing features and advantages, as well as others, will be described in detail in the following description of specific embodiments given by way of illustration and not limitation with reference to the accompanying drawings, in which:

FIG. 1 is a schematic and partial perspective view of an optical filter according to one embodiment;

FIG. 2 is a flowchart illustrating steps of a method for designing and optimizing the optical filter of FIG. 1 according to one embodiment;

FIG. 3 is a comparative graph illustrating the resilience to the incidence angle of different optical filters; and

FIG. 4 is a schematic and partial perspective view of an optical filter according to one embodiment.

### DESCRIPTION OF EMBODIMENTS

Same elements have been designated by like references in the various figures. In particular, the structural and/or functional elements that are common among the various embodiments may have the same references and may dispose identical structural, dimensional and material properties.

For the sake of clarity, only the steps and elements useful for an understanding of the embodiments described herein have been illustrated and detailed. In particular, the various applications of the optical filters in the present description, inter alia the various optical devices that may incorporate these filters, have not been detailed, the described embodiments being compatible with all or most of the usual optical applications and devices that implement at least one optical filter, possibly with adaptations within the reach of the person skilled in the art upon reading the present description.

Unless indicated otherwise, when reference is made to two elements connected together, this signifies a direct connection without any intermediate elements other than conductors, and when reference is made to two elements coupled together, this signifies that these two elements can be connected or coupled via one or more other elements.

In the following disclosure, unless specified otherwise, when reference is made to absolute positional qualifiers, such as the terms “front”, “back”, “top”, “bottom”, “left”, “right”, etc., or to relative positional qualifiers, such as the terms “above”, “below”, “higher”, “lower”, etc., or to qualifiers of orientation, such as “horizontal”, “vertical”, etc., reference is made to the orientation of the figures.

Unless specified otherwise, the expressions “around”, “approximately”, “substantially” and “in the order of” signify within 10% or 10°, and preferably within 5% or 5°.

In the following description, the terms “insulating” and “conductive” mean, respectively, unless specified otherwise, electrically insulating and electrically conductive.

Unless specified otherwise, the expression “in contact with” means “in mechanical contact with”.

In the following description, the expression “transmission of a filter” refers to the ratio between the intensity of a radiation leaving the filter and the intensity of the radiation entering the filter.

In the following description, the expression “central wavelength of a filter” refers to the wavelength that is at the center of the transmission wavelength range of the filter in question.

In the following description, the expression “resilience to the incidence angle of a filter” refers to the ability of the filter to transmit a radiation that is inclined relative to the optical axis, i.e. inclined relative to a direction orthogonal to a face of the filter intended to be illuminated by the radiation.

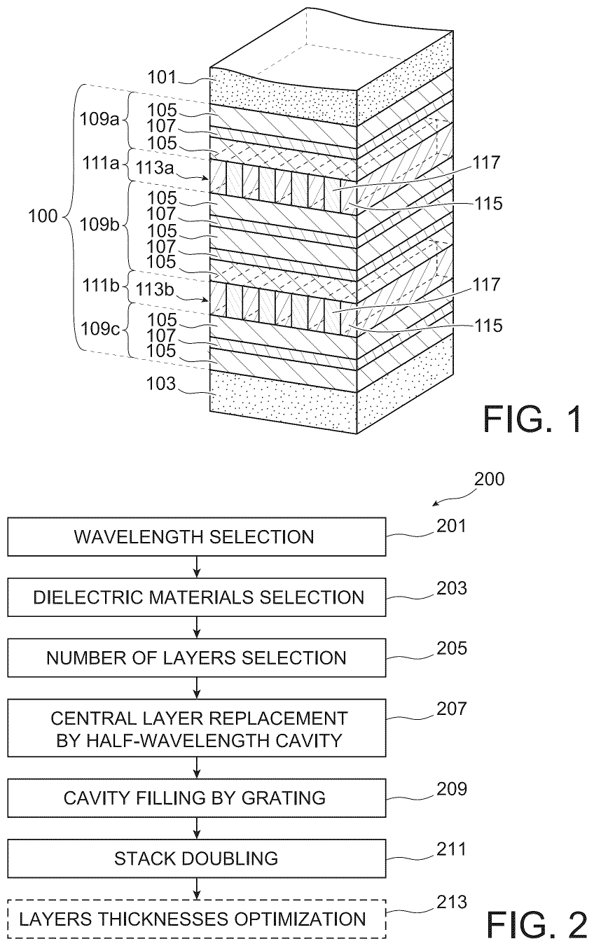

FIG. 1 is a schematic and partial perspective view of an optical filter 100 according to one embodiment.

The filter 100 is, for example, intended to be placed opposite a pixel array of an image sensor, for example to form a multispectral or hyperspectral sensor. The filter 100 is then, for example, adapted to transmit an incident radiation predominantly in a first wavelength range and according to a first polarization to certain pixels of the sensor, and predominantly in at least a second wavelength range, different from the first wavelength range, and/or according to at least a second polarization, different from the first polarization, to other pixels of the sensor.

As a variant, the optical filter 100 is adapted to transmit an incident radiation predominantly in a single wavelength range and according to a single polarization. Furthermore, the filter 100 may be intended to be associated with devices other than an image sensor.

In the illustrated example, the filter 100 is interposed between an input medium 101, from which a radiation illuminating the filter 100 originates, and an output medium 103, to which the filtered radiation is transmitted. In the case where the filter 100 is intended to be disposed above an image sensor, the input medium 101 is, for example, opposite to the pixel array of the image sensor and the output medium 103 faces the pixel array of the image sensor. For example, the input medium 101 consists of air.

In the example illustrated in FIG. 1, the optical filter 100 comprises alternating dielectric layers 105 and 107. The layers 105 are made of at least one insulating material, or dielectric, having an optical index, or refractive index, n1. Furthermore, the layers 107 are made of at least one other insulating material having an optical index n2 strictly higher than the optical index n1.

For example, the materials of the layers 105 and 107 are selected from:
oxides, for example silicon oxide, titanium oxide, niobium oxide, tantalum oxide, etc.;
nitrides, for example silicon nitride; and
amorphous silicon.

Preferably, the layers 105 are all made of the insulating material with optical index n1 and the layers 107 are all made of the insulating material with optical index n2. This facilitates the design and the manufacture of the filter 100. As an example, the dielectric layers 105 and 107 are respectively made of silicon oxide and of amorphous silicon. In this example, the optical indices n1 and n2 are respectively approximately equal to 1.5 and 3.8, for a radiation with a wavelength of approximately equal to 940 nm.

In the illustrated example, the filter 100 more precisely comprises, between the input medium 101 and the output medium 103, three stacks 109a, 109b and 109c of alternating dielectric layers 105 and 107. In this example, the stack 109b is located between the stacks 109a and 109c. The stacks 109a, 109b and 109c each form a reflector, for example. The stacks 109a, 109b and 109c have, for example, a “Bragg mirror” type structure.

FIG. 1 illustrates an example in which each stack 109a, 109c comprises two layers 105 and one layer 107 in an alternating manner, i.e. one layer 107 interposed between two layers 105. Furthermore, in this example, the stack 109b comprises three layers 105 and two layers 107 in an alternating manner, i.e. each layer 107 of the stack 109b is interposed between two adjacent layers 105. However, this example is not limiting and each stack 109a, 109b, 109c may, as a variant, comprise numbers of layers 105 and 107 different from the illustrated ones.

Each dielectric layer 105, 107 has, for example, a thickness E1 known as “quarter-wavelength” or “λ/4n”, i.e. a thickness substantially equal to the central wavelength λ of the optical filter 100 divided by four times the optical index n1, n2 of the layer.

According to one embodiment, the optical filter 100 further comprises resonant cavities 111a and 111b. In the example illustrated in FIG. 1, the resonant cavity 111a is interposed between the stacks 109a and 109b and the resonant cavity 111b is interposed between the stacks 109b and 109c.

Each resonant cavity 111a, 111b comprises, for example, a polarizing filter 113a, 113b. In the illustrated example, the resonant cavities 111a and 111b have a thickness greater than or equal to “2*λ/4n”, i.e. a thickness greater than or equal to twice the central wavelength λ of the optical filter 100 divided by four times the optical index n1, n2 of the cavity 111a, 111b. As a variant, each resonant cavity 111a, 111b has a thickness equal to at least k times the thickness E1 of the material constituting the dielectric layer 107, where k is an integer greater than or equal to two. In the illustrated example, each polarizing filter 113a, 113b extends vertically over the entire thickness of the resonant cavity 111a, 111b and extends laterally over the entire surface of the resonant cavity 111a, 111b. In this example, each polarizing filter 113a, 113b occupies the entire internal volume of the resonant cavity 111a, 111b.

In the illustrated example, each polarizing filter 113a, 113b comprises a periodic structure having alternating bars 115 and 117 parallel to each other, the bars 115 and 117 extending laterally along a substantially horizontal direction. The bars 115 are, for example, made of an insulating material having an optical index n3 and the bars 117 are, for example, made of another insulating material having an optical index n4 strictly higher than the optical index n3.

Preferably, the bars 115 are made of the same material as the dielectric layers 105, i.e. the insulating material with an optical index n1, and the bars 117 are made of the same material as the dielectric layers 107, i.e. the insulating material with an optical index n2. This simplifies the design and the manufacture of the optical filter 100.

Although FIG. 1 illustrates an example in which the optical filter 100 comprises two resonant cavities 111a and 111b, this example is not limiting and the optical filter 100 may, as a variant, comprise a number of resonant cavities strictly greater than two, each resonant cavity then being, for example, interposed between stacks of alternating layers 105 and 107 analogous to the stacks 109a, 109b and 109c. Increasing the number of resonant cavities in the structure leads to widen the range of wavelengths transmitted by the optical filter 100.

Each resonant cavity 111a, 111b has, for example, a thickness E2 known as “half-wavelength” or “λ/2n”, i.e. a thickness substantially equal to approximately the central wavelength λ of the optical filter 100 divided by twice an effective optical index neff of the resonant cavity. As a variant, each resonant cavity 111a, 111b has a thickness equal to k times the thickness E2.

An advantage of the optical filter 100 is that it combines an interference filtering function in wavelengths with a polarization filtering function (polarizer) without loss of light intensity and while exhibiting a resilience to the incidence angle much higher than that of existing polarizing filters. In addition, an advantage of the optical filter 100 is that, in the case where only two materials with different optical indices n1 and n2 are used to make the dielectric layers and the resonant cavities of the filter structure, the manufacture of the optical filter 100 requires the etching of only one of these two materials. This facilitates the manufacture of the optical filter 100.

FIG. 2 is a flowchart illustrating steps of a method 200 for designing and optimizing the optical filter 100 of FIG. 1 according to one embodiment.

In the case where the optical filter 100 is intended to be integrated into a multispectral or hyperspectral sensor, the steps described below are, for example, implemented for each part of the filter intended to be placed opposite at least one pixel of an image sensor and adapted to transmit, to this or these pixels, an incident radiation predominantly within a certain wavelength range and according to a certain polarization. As a variant, for example in the case where the filter 100 is intended to perform a global filtering function, the steps described below may be implemented only once for the entire filter.

During a step 201, a central wavelength λ is selected. As an example, the wavelength λ is selected to be approximately equal to 940 nm.

During another step 203, subsequent to the step 201, a selection of dielectric materials is made. Dielectric materials that are transparent to the central wavelength 2 and have the most important possible contrast between the optical indices are, for example, selected in the step 203. For simplicity, the example below considers the case where only two insulating materials with different optical indices—in the present case, silicon oxide (SiO₂, with optical index n1) and amorphous silicon (aSi, with optical index n2>n1)—are used to make the dielectric layers 105 and 107 and the bars 115 and 117 of the polarizing filters 113a and 113b. However, those skilled in the art will of course be able, based on the information provided in the present description, to transpose this example to cases in which more than two different insulating materials are used to manufacture the optical filter 100.

During another step 205, subsequent to the step 203, a selection of the number of dielectric layers is made. Based on the wavelength λ and the selection of the dielectric materials, a Bragg mirror type stack is designed, comprising, between the input medium 101 and the output medium 103, a multiple N of bilayers (where N is a non-zero integer, for example equal to 4) of silicon oxide and amorphous silicon, plus a layer of silicon oxide. In other words, this amounts to forming a stack consisting of an alternation of 2*N layers of material with index n2 and of 2*N+1 layers of material with index n1, the bottom and top layers of the stack being made of material with index n1 (i.e. silicon oxide, in this example). The selection of the number N depends, for example, on the contrast between the optical indices (the difference between n1 and n2, in this example): the lower the contrast between the optical indices is, the greater the number N is in order to optimize rejections of the filter.

The table below details an example of such a stack, the dielectric layers being numbered in an ascending order from the input medium 101 to the output medium 103. In this table, the thickness of each layer is expressed in multiples of 24n and in nanometers (nm) and the letter “n” represents the optical index at the wavelength λ in question.

TABLE 1

| Layer No | Material | n | Thickness (λ/4n) | Thickness (nm) |
|---|---|---|---|---|
| 1 | SiO₂ | 1.46 | 1 | 162 |
| 2 | aSi | 3.78 | 1 | 62 |
| 3 | SiO₂ | 1.46 | 1 | 162 |
| 4 | aSi | 3.78 | 1 | 62 |
| 5 | SiO₂ | 1.46 | 1 | 162 |
| 6 | aSi | 3.78 | 1 | 62 |
| 7 | SiO₂ | 1.46 | 1 | 162 |

In the above example, the stack comprises two alternations aSi/SiO₂ located on either side of an aSi layer (layer n° 4) with a thickness of λ/4n.

During another step 207, subsequent to the step 205, the central dielectric layer of the stack (i.e. the layer n° 5, in the above example) is replaced by a half-wavelength resonant cavity. This makes it possible to make a filter that transmits a wavelength range centered on the wavelength λ.

The table below details the structure obtained at the end of the step 207 in the case of the previous example:

TABLE 2

| Layer No | Material | n | Thickness (λ/4n) | Thickness (nm) |
|---|---|---|---|---|
| 1 | SiO₂ | 1.46 | 1 | 162 |
| 2 | aSi | 3.78 | 1 | 62 |
| 3 | SiO₂ | 1.46 | 1 | 162 |
| 4 | aSi | 3.78 | 2 | 124 |
| 5 | SiO₂ | 1.46 | 1 | 162 |
| 6 | aSi | 3.78 | 1 | 62 |
| 7 | SiO₂ | 1.46 | 1 | 162 |

In the above example, the stack comprises two alternations aSi/SiO₂ located on either side of an aSi layer (layer n° 4) with a thickness of 2*λ/4n (=λ/2n). Although the above example details a case in which the resonant cavity has a half-wavelength thickness, this example is not limiting and the cavity may, as a variant, have a thickness equal to an integer multiple greater than two of the half-wavelength. The selection of the thickness of the resonant cavity depends, for example, on the contrast between the optical indices (the difference between n1 and n2, in this example): the lower the contrast is, the greater the thickness of the resonant cavity is in order to obtain a high transmission contrast between a polarization s, i.e. a linear polarization substantially orthogonal to the incidence plane, and a polarization p, i.e. a linear polarization substantially parallel to the incidence plane and substantially orthogonal to the polarization s.

During another step 209, subsequent to the step 207, the resonant cavity, consisting of the central layer of the stack, is filled with a grating forming a polarizing filter. This makes it possible to separate the polarizations s and p. As an example, the grating comprises an alternation of parallel bars of the material of low index n1 and of parallel bars of the material of high index n2 extending in the plane of the resonant cavity orthogonally to the stack.

The thickness of the central layer, and therefore of the resonant cavity, can be adjusted during the step 209 so that, for the desired polarization s or p, the structure has a transmission peak at the central wavelength A selected in the step 201.

The table below details the structure obtained at the end of the step 209 in the case of the previous example, by selecting to transmit the polarization s at the wavelength A:

TABLE 3

| Layer No | Material | n | Thickness (λ/4n) | Thickness (nm) |
|---|---|---|---|---|
| 1 | SiO₂ | 1.46 | 1 | 162 |
| 2 | aSi | 3.78 | 1 | 62 |
| 3 | SiO₂ | 1.46 | 1 | 162 |
| 4 | aSi | 3.78 | — | 156 |
| 5 | SiO₂ | 1.46 | 1 | 162 |
| 6 | aSi | 3.78 | 1 | 62 |
| 7 | SiO₂ | 1.46 | 1 | 162 |

In the above example, the transmission peak of the polarization p is obtained at a wavelength equal to approximately 850 nm.

The structure obtained at the end of the steps 201 to 209 constitutes an optical filter known as a “sharp” filter, i.e. one whose transmission decreases sharply as the incidence angle increases. As an example, when the filter is illuminated by a radiation with a wavelength λ equal to 940 nm, the transmission is, for incidence angles greater than 10°, less than 20% of the maximum transmission obtained for an incidence angle of zero (radiation oriented along the optical axis).

During another step 211, subsequent to the step 209, the stack described above is doubled, or duplicated. The step 211 has the effect of increasing the number of resonant cavities 111a, 111b, thereby widening the maximum transmission window of the filter 100.

The two stacks are superimposed so that the bottom layer of the upper stack (layer 7, in the above example) coincides with the top layer of the lower stack (layer 1, in this example). In addition, the top layer of the upper stack (layer 1, in the above example) and the bottom layer of the lower stack (layer 7, in this example) are, for example, removed. The optical filter 100 previously described in relation to FIG. 1 is thus obtained.

The table below details the structure obtained at the end of the step 211 in the case of the previous example, by selecting to transmit the polarization s at the wavelength λ:

TABLE 4

| Layer No | Reference | Material | Thickness (λ/4n) |
|---|---|---|---|
| 1 | 105 | SiO₂ | 1 |
| 2 | 107 | aSi | 1 |
| 3 | 105 | SiO₂ | 1 |
| 4 | 111a | aSi/SiO₂ | 2 |
| 5 | 105 | SiO₂ | 1 |
| 6 | 107 | aSi | 1 |
| 7 | 105 | SiO₂ | 1 |
| 8 | 107 | aSi | 1 |
| 9 | 105 | SiO₂ | 1 |
| 10 | 111b | aSi/SiO₂ | 2 |
| 11 | 105 | SiO₂ | 1 |
| 12 | 107 | aSi | 1 |
| 13 | 105 | SiO₂ | 1 |

At the end of the steps 201 to 211, a quarter-wavelength stack comprising two resonant cavities 111a and 111b is obtained. In this stack, the greater the number of bilayers interposed between the resonant cavities 111a and 111b is, the narrower the range of wavelengths transmitted by the optical filter 100 is.

The polarizing filters 113a and 113b of the resonant cavities 111a and 111b of the structure are adapted to filter a same polarization. In the case where the resonant cavities 111a and 111b each comprise a grating of bars forming a polarizing filter, the bars of the two gratings are, for example, substantially parallel to each other.

During an optional step 213, subsequent to the step 211, the thicknesses of the layers of the optical filter 100 are optimized, for example by using a computer program product comprising program code instructions leading to the implementation of a process for optimizing the filter 100 when executed by a computer.

As an example, the thickness of each layer of the stack of the optical filter 100 is an adjustment parameter. The initial thicknesses considered for the optimization are, for example, those in Table 4 above (quarter-wavelength layers and half-wavelength resonant cavities). The boundary conditions are set, for example, by:
the central wavelength λ of the optical filter 100;
a range of incidence angles for which it is desired that the optical filter 100 be functional; and
minimum and maximum thicknesses.

The optimization step 213 advantageously allows for further improvement of the resilience of the optical filter 100 to the incidence angle. As an example, the step 213 is performed by using a computer-implemented multilayer optical calculation software.

The table below details an example of optimization of the structure obtained at the end of the step 213 in the case of the previous example, by selecting to transmit the polarization s at the wavelength λ:

TABLE 5

| Layer No | Material | Thickness (λ/4n) |
|---|---|---|
| 1 | SiO₂ | 2.254 |
| 2 | aSi | 0.884 |
| 3 | SiO₂ | 0.664 |
| 4 | aSi/SiO₂ | 2.407 |
| 5 | SiO₂ | 0.729 |
| 6 | aSi | 0.895 |
| 7 | SiO₂ | 0.804 |
| 8 | aSi | 1.407 |
| 9 | SiO₂ | 0.504 |
| 10 | aSi/SiO₂ | 2.435 |
| 11 | SiO₂ | 0.679 |
| 12 | aSi | 0.926 |
| 13 | SiO₂ | 1.740 |

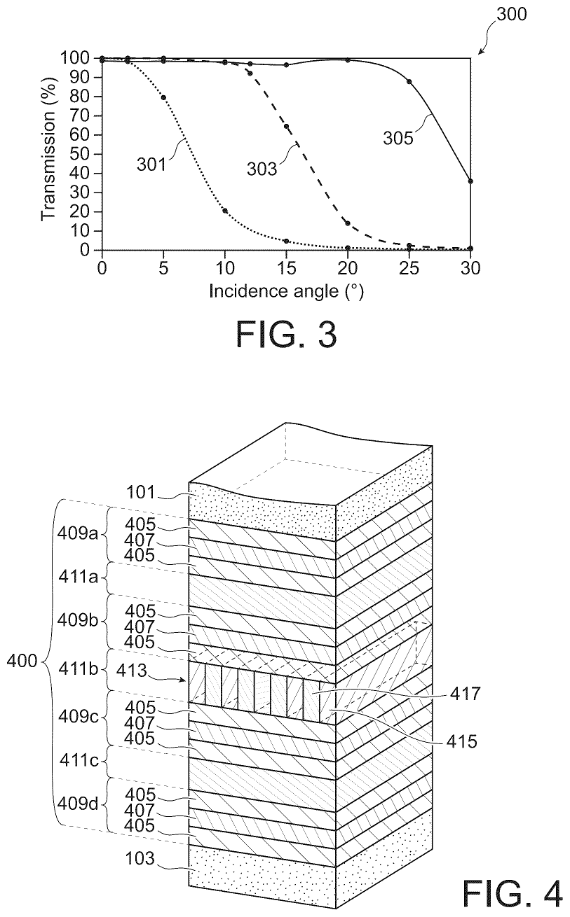

FIG. 3 is a comparative graph illustrating the resilience to the incidence angle (expressed in degrees, °) of different optical filters.

The graph 300 includes three curves 301, 303 and 305 illustrating variations in transmission, expressed as a percentage of the maximum transmission obtained for a zero incidence angle (radiation oriented along the optical axis), as a function of the incidence angle for, respectively:
an optical filter comprising a single resonant cavity (curve 301), for example the optical filter of Table 3;
the non-optimized optical filter 100 of Table 4 (curve 303); and
the optimized optical filter 100 of Table 5 (curve 305).

The graph 300 shows that the use of an optical filter comprising two resonant cavities, such as the optical filter 100, allows to increase the resilience to the incidence angle compared to an optical filter comprising only a single resonant cavity. Furthermore, optimizing the thicknesses of the layers and of the resonant cavities of the optical filter 100 allows to greatly increase the resilience to the incidence angle compared to the non-optimized optical filter 100.

The influence of different parameters of the structure on the performance of the optical filter 100 is detailed below.

The following description takes as an example the case where each polarizing filter 113a, 113b of the optical filter 100 comprises the parallel bars 115 made of the material of low index n1 and the parallel bars 117 made of the material of high index n2 completely filling all the free spaces extending laterally between the bars 115. As an example, the bars 115 each have a width L1 and the bars 117 each have a width L2.

In the following description, the expression “form factor” refers to a ratio between the width L1 and the sum of the widths L1 and L2 (F=L1/(L1+L2), where F refers to the form factor of the grating of bars 115 and 117). In addition, the expression “grating period” refers to the sum of the widths L1 and L2 (T=L1+L2, where T refers to the grating period).

The resilience to the incidence angle of the optical filter 100 is not changed, or is very slightly changed, as a function of the form factor F for values of the form factor F ranging from 0.1 to 0.9.

In addition, in a case where the polarizing filters 113a and 113b of the optical filter 100 have a substantially identical structure and substantially identical dimensions, apart from manufacturing tolerances, the transmission of the filter is not altered in the event of a lateral shift of one polarizing filter relative to the other. In other words, the fact that the bars 115 and 117 of one of the polarizing filters 113a, 113b are not directly above the bars 115 and 117 of the other polarizing filter 113b, 113a does not affect the transmission of the optical filter 100. One advantage is that this facilitates the manufacture of the optical filter 100, for example due to the relaxation of alignment constraints on etching masks used to make the polarizing filters 113a and 113b.

With a constant physical or geometric thickness of the optical filter 100, the selection of the form factor F influences the position of the respective transmission wavelength ranges of the polarizations s and p. In addition, at a constant optical thickness of the optical filter 100, the selection of the form factor F influences the position of the transmission wavelength range of the polarization p without modifying, or by slightly modifying, the position of the transmission wavelength range of the polarization s. In the case of a multispectral or hyperspectral sensor comprising the optical filter 100, modifying the shape factor F facing different pixels of the image sensor makes it possible to transmit, to these pixels, radiations in different wavelength transmission ranges while maintaining a constant filter thickness. This facilitates the manufacture of the optical filter 100.

Another way to modify the transmission wavelength range of the optical filter 100 is to vary the total thickness of the layer stack and/or the thickness of the resonant cavities 111a and 111b. The thicker the resonant cavities 111a and 111b are, the more the transmission wavelength range of the optical filter 100 is shifted toward the high wavelengths.

Furthermore, the thicker the resonant cavities 111a and 111b are, the longer the transmission wavelength ranges of the polarizations s and p are distant. Thus, increasing the thickness of the resonant cavities 111a and 111b makes it possible, for example, to distance the transmission wavelength ranges of the polarizations s and p in a case where the contrast between the optical indices n1 and n2 is low.

The period T of the bar grating of each polarizing filter allows the position of the transmission wavelength range of the polarization s to be adjusted relative to the transmission wavelength range of the polarization p. In particular, increasing the period T tends to bring these ranges closer to each other. Furthermore, when the period T of the grating increases, the width of the transmission wavelength range of the polarization s remains substantially constant while the width of the transmission wavelength range of the polarization p decreases. The form factor F has an influence on the transmission wavelength ranges of the polarizations s and p similar to the one of the period T of the grating.

In addition, it is possible to provide that the polarizing filter 113a has a form factor F different from that of the polarizing filter 113b, for example a form factor Fa equal to approximately 0.45 for the polarizing filter 113a and a form factor Fb equal to approximately 0.9 for the polarizing filter 113b. This makes it possible to reduce the transmission of the polarization p without reducing the transmission of the polarization s.

Furthermore, the greater the difference between the indices n1 and n2 is, the longer the transmission wavelength range of the polarization s is distant from the transmission wavelength range of the polarization p.

As an example, the optical filter 100 comprises groups of four regions adapted to filter radiations according to respectively four different polarization orientations, for example linear polarizations according to respectively four directions respectively forming angles of 0°, 90°, 45° and 135° with respect to a reference direction. Each group of four regions is, for example, intended to be placed opposite a group of four adjacent pixels of an image sensor. In this example, the bars 115 and 117 of the polarizing filters 113a and 113b of the four regions of the optical filter 100 extend laterally in respectively four directions respectively forming angles of 0°, 90°, 45° and 135° with respect to the reference direction.

FIG. 4 is a schematic and partial perspective view of an optical filter 400 according to one embodiment.

In a manner analogous to the filter 100, the filter 400 is, for example, intended to be placed opposite a pixel array of an image sensor, for example to form a multispectral or hyperspectral sensor. As a variant, the optical filter 400 is adapted to transmit an incident radiation predominantly in a single wavelength range and according to a single polarization.

In the example illustrated in FIG. 4, the optical filter 400 comprises alternating dielectric layers 405 and 407. The layers 405 are made of at least one insulating material, or dielectric, having an optical index, or refractive index, n5. In addition, the layers 407 are made of at least another insulating material having an optical index n6 strictly higher than the optical index n5.

As an example, the materials of the layers 405 and 407 are selected from:
oxides, for example silicon oxide, titanium oxide, niobium oxide, tantalum oxide, etc.;
nitrides, for example silicon nitride; and
amorphous silicon.

Preferably, the layers 405 are made of the same insulating material with an optical index n5 and the layers 407 are made of the same insulating material with an optical index n6. This facilitates the design and the manufacture of the filter 400. As an example, the dielectric layers 405 and 407 are respectively made of silicon oxide and silicon nitride. In this example, the optical indices n5 and n6 are respectively approximately equal to 1.5 and 2.02 for a radiation with a wavelength of approximately equal to 550 nm.

In the illustrated example, the filter 400 more precisely comprises, between the input medium 101 and the output medium 103, four stacks 409a, 409b, 409c and 409d of alternating dielectric layers 405 and 407. In this example, the stack 409b is located between the stacks 409a and 409c and the stack 409c is located between the stacks 409b and 409d. The stacks 409a, 409b, 409c and 409d each form a reflector, for example.

FIG. 4 illustrates an example in which each stack 409a, 409b, 409c, 409d comprises two layers 405 and one layer 407 in an alternating manner, i.e. one layer 407 interposed between two layers 405. However, this example is not limiting, and each stack 409a, 409b, 409c, 409d may, as a variant, comprise numbers of layers 405 and 407 different than those illustrated.

Each dielectric layer 405, 407 has, for example, a thickness E3 known as “quarter wavelength” or “λ/4n”, i.e. a thickness substantially equal to the central wavelength λ of the optical filter 400 divided by four times the optical index n5, n6 of the layer.

According to one embodiment, the optical filter 400 further comprises resonant cavities 411a, 411b and 411c. In the example illustrated in FIG. 4, the resonant cavity 411a is interposed between the stacks 409a and 409b, the resonant cavity 411b is interposed between the stacks 409b and 409c and the resonant cavity 411c is interposed between the stacks 409c and 409d.

Each resonant cavity 411a, 411c is, for example, made up of a layer of material with an optical index n6 having a thickness equal to at least k times twice the thickness E3 of the layers 407. In addition, the resonant cavity 411b comprises, for example, a polarizing filter 413. In the illustrated example, the polarizing filter 413 extends vertically over the entire thickness of the resonant cavity 411b and extends laterally over the entire surface of the resonant cavity 411b. In this example, the polarizing filter 413 occupies the entire internal volume of the resonant cavity 411b. Although FIG. 4 illustrates an example in which the polarizing filter 413 is integrated into the resonant cavity 411b, this example is not limiting and the polarizing filter 413 may, as a variant, be integrated into the resonant cavity 411a or into the resonant cavity 411c.

In the illustrated example, the polarizing filter 413 comprises a periodic structure comprising alternating bars 415 and 417 parallel to each other, the bars 415 and 417 extending laterally along a substantially horizontal direction. The bars 415 are, for example, made of a metallic material having an optical index n7 and the bars 417 are, for example, made of an insulating material having an optical index n8 strictly higher than the optical index n7. As an example, the bars 415 are made of a metal, such as aluminum, silver, etc., or of a metallic alloy. The bars 417 are, for example, made of one of the materials listed above for the layers 405 and 407.

As an example, the bars 415 are made of aluminum and the bars 417 are made of silicon oxide.

Although FIG. 4 illustrates an example in which the optical filter 400 comprises two resonant cavities 411a and 411c without a polarizing filter and a single resonant cavity 411b comprising a polarizing filter, this example is not limiting and the optical filter 400 may, as a variant, comprise numbers of resonant cavities different than the illustrated ones, provided that at least one of the resonant cavities comprises a polarizing filter.

Each resonant cavity 411a, 411b, 411c has, for example, a thickness E4 known as “half-wavelength” or “λ/2n”, i.e. a thickness substantially equal to approximately the central wavelength λ of the optical filter 400 divided by twice an effective optical index neff of the resonant cavity. As a variant, each resonant cavity 411a, 411b, 411c has a thickness equal to k times the thickness E4.

An advantage of the optical filter 400 is that it combines an interference filtering function in wavelengths with a polarization filtering function (polarizer) without loss of light intensity and while exhibiting a resilience to the incidence angle much higher than that of existing polarizing filters.

Various embodiments and variants have been described. Those skilled in the art will understand that certain features of these various embodiments and variants could be combined and other variants will readily occur to those skilled in the art.

In particular, those skilled in the art will be able to plan, based on the information provided in the present description, to make the bars 115 of the optical filter 100 from a metallic material, for example a material similar to that of the bars 415 of the optical filter 400. Furthermore, a person skilled in the art will be able to plan, based on the information provided in the present description, to make the bars 415 of the optical filter 400 from a dielectric material, for example a material similar to that of the bars 115 of the optical filter 100.

Finally, the practical implementation of the embodiments and variants described herein is within the capabilities of those skilled in the art based on the functional indications provided hereinabove. In particular, the described embodiments are not limited to the specific examples of materials and dimensions mentioned in the present description.

1. An optical filter comprising a superposition of:
at least first and second resonant cavities; and
at least a first polarizing filter,
the filter further comprising:
A) a second polarizing filter, the first and second polarizing filters being respectively located in the first and second resonant cavities; or
B) a third resonant cavity interposed between the first and second resonant cavities, each first polarizing filter being located in one of the first, second and third resonant cavities.

2. The optical filter according to claim 1, in option B), comprising a single first polarizing filter preferably located in the third resonant cavity.

3. The optical filter according to claim 1, wherein each resonant cavity is interposed between stacks each comprising an alternation of:
at least two first layers of a first insulating material having a first optical index; and
at least one second layer of a second insulating material having a second optical index strictly higher than the first optical index.

4. The optical filter according to claim 3, wherein the first and second insulating materials are selected from:
oxides, for example silicon oxide, titanium oxide, niobium oxide, tantalum oxide, etc.;
nitrides, for example silicon nitride; and
amorphous silicon.

5. The optical filter according to claim 3, wherein each first layer and each second layer has a quarter-wavelength thickness.

6. The optical filter according to claim 1, wherein each resonant cavity has a half-wavelength thickness.

7. The optical filter according to claim 1, wherein each polarizing filter comprises a grating of alternating parallel bars comprising:
first bars made of a third material having a third optical index; and
second bars made of a fourth insulating material having a fourth optical index strictly higher than the third optical index.

8. The optical filter according to claim 7, wherein each resonant cavity is interposed between stacks each comprising an alternation of:
at least two first layers of a first insulating material having a first optical index; and
at least one second layer of a second insulating material having a second optical index strictly higher than the first optical index,
the third and fourth materials being respectively identical to the first and second materials.

9. The optical filter according to claim 7, wherein the third material is a metallic material, for example silver or aluminum.

10. The optical filter according to claim 7, in option A), wherein the bar gratings of the first and second polarizing filters have an identical pitch.

11. The optical filter according to claim 9, in option A), wherein the bar gratings of the first and second polarizing filters have different pitches.

12. The optical filter according to claim 1, intended to be placed opposite a pixel array of an image sensor, the optical filter being adapted to transmit an incident radiation predominantly in a first wavelength range and according to a first polarization to certain pixels of the sensor, and predominantly in at least a second wavelength range, different from the first wavelength range, and/or according to at least a second polarization, different from the first polarization, to other pixels of the sensor.

13. A multispectral or hyperspectral sensor comprising an image sensor having a pixel array opposite which an optical filter according to claim 1 is located.
